(19) United States
(12) Patent Application Publication
(10) Pub. No.: US 2010/0052742 A1
(43) Pub. Date: Mar. 4, 2010

(54) LIMIT SIGNAL GENERATOR, PWM CONTROL CIRCUIT, AND PWM CONTROL METHOD THEREOF

(76) Inventors: Chun-Teh Chen, Hsin-Chu (TW); Ren-Yi Chen, Hsin-Chu (TW); Da-Chun Wei, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 12/200,908

(22) Filed: Aug. 28, 2008

(51) Int. Cl. H03K 4/06

(52) U.S. Cl. 327/134

(57) ABSTRACT

A PWM control circuit is disclosed. An oscillator generates a triangular signal, received by a limit signal generator to produce a limit signal accordingly. Corresponding to a rising period of the triangular signal, the limit signal sequentially experiences a first holding period, a rising period and a second holding period, wherein the limit signal has a first predetermined value during the first holding period and a second predetermined value during the second holding period. A compare/control circuit compares the limit signal with a detection signal corresponding to a current through a power switch, and controls the power switch accordingly.

### BACKGROUND OF THE INVENTION

1. Field of the Invention

The present invention relates to a power supply, and more particularly, to a pulse width modulation (PWM) control circuit for use in a power supply.

2. Description of the Prior Art

The technology of pulse width modulation has been widely applied to a variety of switching power supplies for controlling or regulating output power. In order to avoid permanent damage occurring to a power supply, the power supply is normally embedded with protection circuits such as an over-voltage protection circuit, an over-current protection circuit, and so forth. In general, the power supply is also installed with a protection mechanism for limiting output power regarding overloading or output shorting situations.

Please refer to FIG. 1, which is a schematic diagram showing a prior-art pulse width modulation (PWM) power supply 100. A controller 106 functions to generate a PWM signal for controlling on/off states of a power switch 102. When the power switch 102 is turned on, a power voltage V_{IN} will charge the primary winding of a transformer 104 so that the current flowing through the primary winding is growing gradually. When the power switch 102 is turned off, the energy stored in the transformer 104 can be released for charging an output capacitor via the secondary winding. The resistor R_{CS} is connected with the power switch 102 in series. Accordingly, the voltage drop V_{CS} across the resistor R_{CS} is corresponding to the current flowing through the power switch 102 and/or the primary winding. When the voltage drop V_{CS} is greater than or equal to a predetermined value such as the value of a limit signal V_{LIMIT}, the current, flowing through the power switch 102 and/or the primary winding, is then estimated to be an over current. Under such over-current situation, the controller 106 functions to turn off the power switch 102 for ceasing an increase of the current flowing through the primary winding. In other words, the limit signal V_{LIMIT} can be utilized to put a limit of maximum power output to the operation of the PWM power supply 100.

However, if the limit signal V_{LIMIT} is set as a constant, the maximum output power may change in response to a variation of the power voltage V_{IN} due to an occurrence of signal propagation delay. When the voltage drop V_{CS} is greater than or equal to the value of the limit signal V_{LIMIT}, a signal delay time t_{DELAY} is required for the controller 106 to complete turning off the power switch 102. In the process during the signal delay time t_{DELAY}, the current flowing through the primary winding is still increasing, and the growth amount of the current is approximately proportional to the contemporary voltage level of the power voltage V_{IN}. That is, the maximum power output is actually increased following the increase of the power voltage V_{IN}.

A solution of the aforementioned problem is provided by Yang et al. in U.S. Pat. No. 6,674,656 filed on Oct. 28, 2002, entitled “PWM controller having a saw-limiter for output power limit without sensing input voltage”, which is referred to as a '656 patent hereinafter. FIG. 2 presents a schematic diagram briefing a methodological construct regarding the '656 patent. In the methodological construct provided by the '656 patent, the limit signal V_{LIMIT} is not a constant. A saw-tooth signal generated by an oscillator 204 is furnished to a waveform converter 202. The waveform converter 202 then performs slope-adjusting, clamping, and level-shifting operations on the saw-tooth signal for generating the limit signal V_{LIMIT} as shown in FIG. 2. The value of the limit signal V_{LIMIT} is changing with time during each period. As shown in FIG. 2, during each period, the value of the limit signal V_{LIMIT} is rising from a lowest voltage and is eventually clamped at a highest voltage. FIG. 3 illustrates the waveforms regarding the limit signal V_{LIMIT} and two different voltage drops V_{CS} generated in accordance with an embodiment of the '656 patent. Referring to FIG. 3, the waveform of a voltage V_{CS}(V_{INHIGH}) represents the waveform of the voltage drop V_{CS} corresponding to a higher power voltage V_{IN}, and the waveform of a voltage V_{CS}(V_{INLOW}) represents the waveform of the voltage drop V_{CS} corresponding to a lower power voltage V_{IN}. Based on the waveforms shown in FIG. 3, it is obvious that the slope of the voltage V_{CS}(V_{INHIGH}) is higher as the corresponding power voltage V_{IN} is higher. Accordingly, when the power voltage V_{IN} is higher, the voltage V_{CS}(V_{INHIGH}) is rising quickly so as to reach a lower voltage of the limit signal V_{LIMIT}, and the problem of unstable maximum output power, resulting from the occurrence of signal propagation delay, can be roughly solved.

### SUMMARY OF THE INVENTION

In accordance with an embodiment of the present invention, a limit signal generator for converting a triangular signal into a limit signal is provided. The limit signal comprises a first holding period, a second holding period and a rising period. The limit signal sequentially experiences the first holding period, the rising period and the second holding period since an initial rise regarding a period of the triangular signal. The limit signal generator comprises a scaler, an adder, a first clamper, and a second clamper. The scaler functions to determine a slope of the limit signal during the rising period. The adder functions to determine a value of the limit signal during the rising period by subtracting an offset signal from the triangular signal. The first damper is utilized for clamping the limit signal to be a first predetermined value during the first holding period. The second damper is utilized for clamping the limit signal to be a second predetermined value during the second holding period.

An embodiment of the present invention provides a pulse width modulation (PWM) control circuit comprising an oscillator, a limit signal generator, a power switch, and a control circuit. The oscillator functions to generate a triangular signal. The limit signal generator is utilized for generating a limit signal based on the triangular signal received. The limit signal comprises a first holding period, a second holding period and a rising period. The limit signal sequentially experiences the first holding period, the rising period and the second holding period since an initial rise regarding a period of the triangular signal. The limit signal has a first predetermined value during the first holding period and a second predetermined value during the second holding period. The control circuit functions to control the power switch by comparing the limit signal with a detection signal regarding a current flowing through the power switch.

An embodiment of the present invention provides a pulse width modulation control method. The pulse width modulation control method comprises receiving a triangular signal, performing a limit signal generation process for outputting a limit signal based on the triangular signal since an initial rise regarding a period of the triangular signal, and comparing the limit signal with a detection signal regarding a current flowing through a power switch for controlling the power switch. The limit signal generation process comprises retaining the limit signal to be a first predetermined value during a first holding period, increasing the limit signal gradually from the first predetermined value upwards to a second predetermined value during a rising period, and retaining the limit signal to be the second predetermined value during a second holding period.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing a prior-art pulse width modulation (PWM) power supply.

FIG. 2 presents a schematic diagram briefing a methodological construct regarding the '656 patent.

FIG. 3 illustrates the waveforms regarding the limit signal V_{LIMIT} and two different voltage drops V_{CS} generated in accordance with an embodiment of the '656 patent.

FIG. 4A is a circuit diagram schematically showing a power supply in accordance with an embodiment of the present invention.

FIG. 4B shows the timing relationship regarding the limit signal V_{LIMIT} and the triangular signal V_{OSC} generated according to an embodiment of the present invention.

FIG. 5A shows the related signal waveforms during a period shown in FIG. 3 so as to illustrate the potential problem caused by the limit signal V_{LIMIT} in FIG. 2.

FIG. 5B shows the related signal waveforms during a period regarding the operation of the power supply shown in FIG. 4A so as to illustrate the potential result generated based on the limit signal V_{LIMIT} in FIG. 4B.

FIG. 6 is a schematic diagram showing a limit signal generator for generating the limit signal V_{LIMIT} in FIG. 4B.

FIG. 7 shows a circuit embodiment of the limit signal generator in FIG. 6.

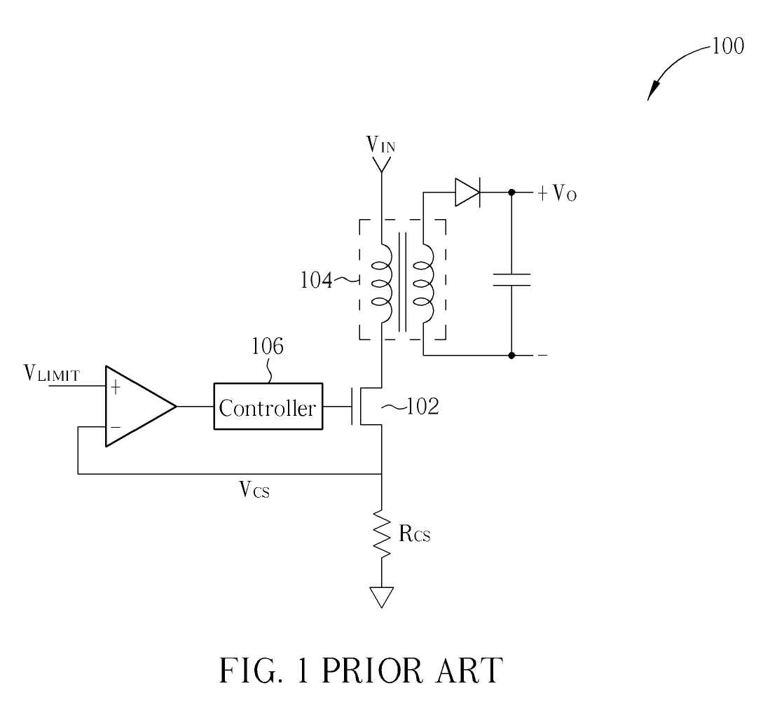

### DETAILED DESCRIPTION

Hereinafter, preferred embodiments of the present invention will be described in detail with reference to the accompanying drawings. Here, it is to be noted that the present invention is not limited thereto.

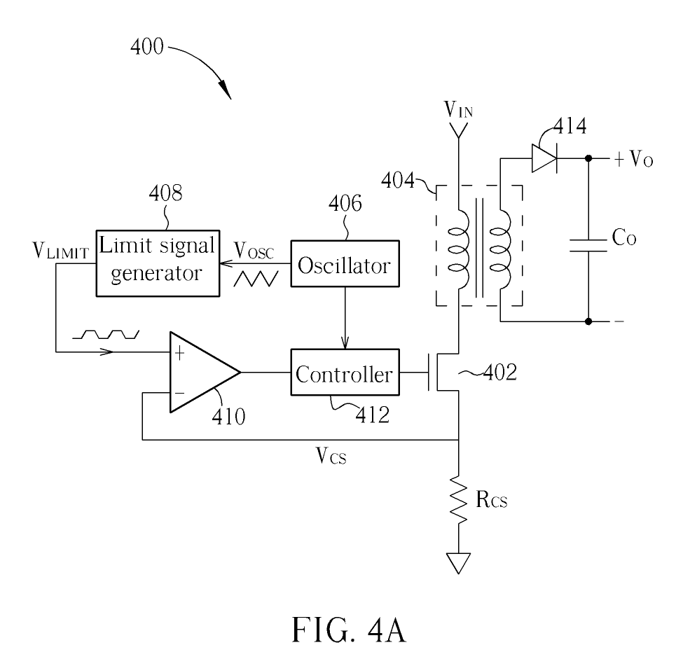

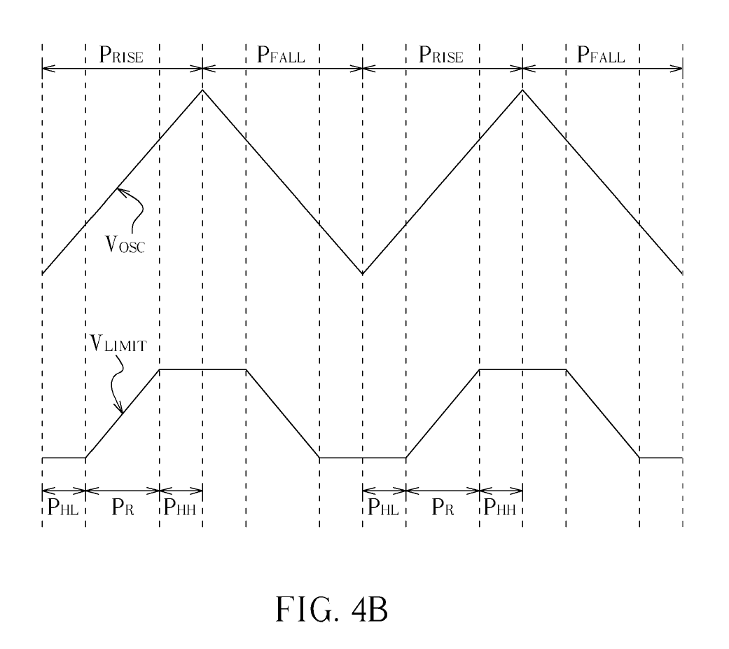

FIG. 4A is a circuit diagram schematically showing a power supply in accordance with an embodiment of the present invention. The power supply 400 is a flyback power converter comprising a power switch 402, a transformer 404, an oscillator 406, a limit signal generator 408, a comparator 410, a controller 412, a resistor R_{CS}, a diode 414, and a rectification load capacitor C_{O}. The controller 412 controls on/off states of the power switch 402 for enabling charging or discharging operation of the transformer 404. The resistor R_{CS} is utilized for detecting the current flowing through the primary winding of the transformer 404 so as to control the output power of the power supply 400. The oscillator 406 functions to generate a triangular signal V_{OSC} forwarded to the limit signal generator 408. The limit signal generator 408 is utilized to generate a limit signal V_{LIMIT} based on the triangular signal V_{OSC}. The detailed explanation on the limit signal generator 408 will be set forth later on. The comparator 410 compares the limit signal V_{LIMIT} with the voltage drop V_{CS} across the resistor R_{CS}. The controller 412 controls the operation of the power switch 402 according to the output of the comparator 410.

Please refer to FIG. 4B, which shows the timing relationship regarding the limit signal V_{LIMIT}, generated by the limit signal generator 408, in conjunction with the triangular signal V_{OSC}. Each period of the triangular signal V_{OSC} includes a rising period P_{RISE} and a falling period P_{FALL}. During the rising period P_{RISE} of the triangular signal V_{OSC}, the limit signal V_{LIMIT} includes three periods, which are a holding period P_{HL}, a rising period P_{R} and a holding period P_{HH} in timing sequence. During the holding period P_{HL} of the limit signal V_{LIMIT}, the limit signal V_{LIMIT} retains a predetermined value such as a voltage V_{HOLD-MIN}. During the rising period P_{R} of the limit signal V_{LIMIT}, the limit signal V_{LIMIT} is increasing with time and rises from the voltage V_{HOLD-MIN} to another predetermined value such as a voltage V_{HOLD-MAX}. During the holding period P_{HH} of the limit signal V_{LIMIT}, the limit signal V_{LIMIT} retains the voltage V_{HOLD-MAX}.

After the power supply 400 is powered, a higher initial output current can be provided for fast boosting the output voltage V_{O} from initial zero level upwards based on the limit signal V_{LIMIT} in FIG. 4B. When the power supply 400 is initially powered, the voltage drop across the rectification load capacitor C_{O} is approximately equal to zero in that the rectification load capacitor C_{O} has not been charged yet, and therefore the voltage drop Vs across the secondary winding of the transformer 404 is approximately equal to zero. Meanwhile, the voltage drop Vp (=Vs*Np/Ns) induced by the primary winding is also approximately equal to zero. The Np and Ns are the coil numbers of the primary winding and the secondary winding respectively. That is, when the power supply 400 is initially powered by the power voltage V_{IN} and the power switch 402 is concurrently turned on, the input energy is transferred directly from the primary winding to the secondary winding without storing energy in the transformer 404 according to well-known transformer performance. Consequently, there is a high instant current flowing through the primary winding; meanwhile, the secondary winding induces a corresponding current for charging the rectification load capacitor C_{O}. The high instant current, flowing through the primary winding, can be determined by the resistor R_{CS} and the contemporary value of the limit signal V_{LIMIT}.

After the rectification load capacitor C_{O} is charged to some extent based on the current induced by the secondary winding, the charging operation on the rectification load capacitor C_{O} is disabled by the voltage drop across the rectification load capacitor C_{O} when the power switch 402 is turned on. In the meantime, the primary winding of the transformer 404 is decoupled from the secondary winding and functions as a single inductor. In view of that, the current flowing through the primary winding of the transformer 404 is then increased gradually with time following the effect of reluctance regarding the primary winding of the transformer 404.

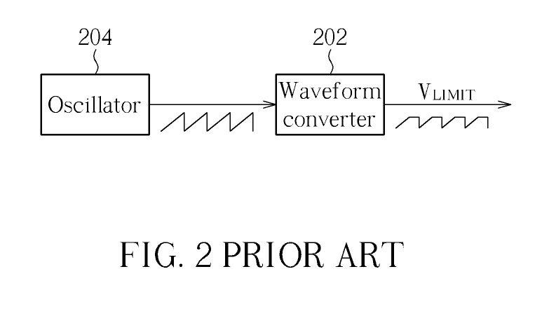

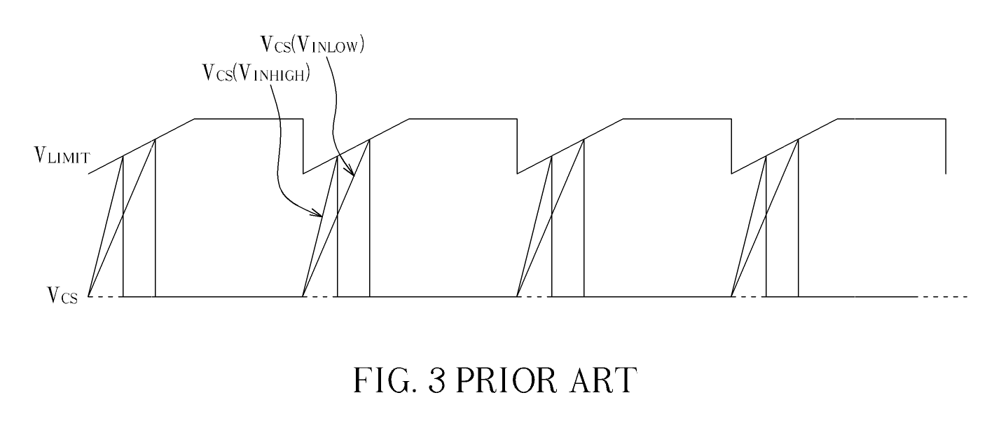

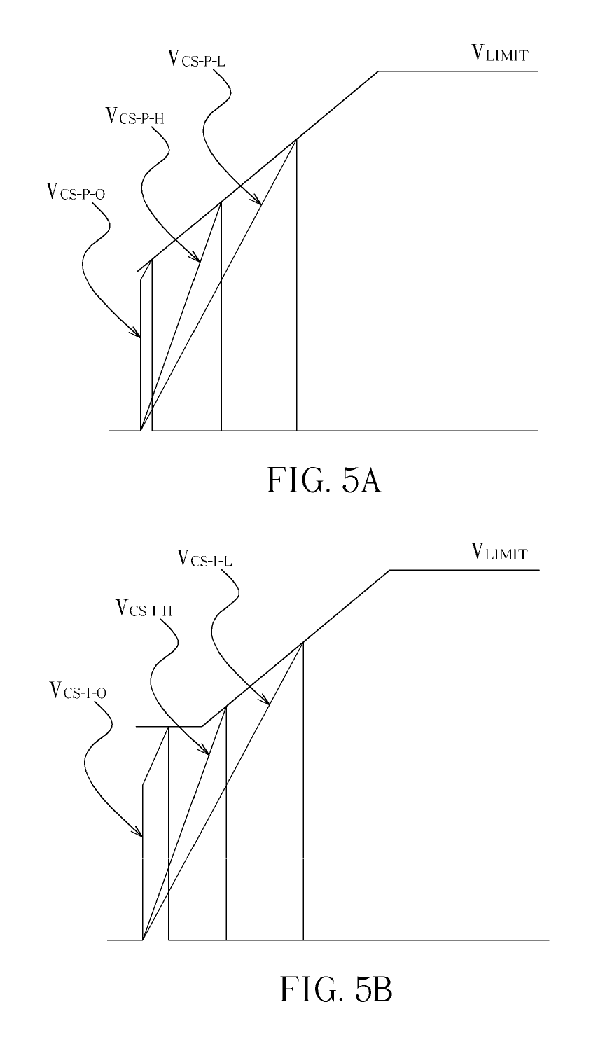

FIG. 5A shows the related signal waveforms during a period shown in FIG. 3 so as to illustrate the potential problem caused by the limit signal V_{LIMIT} in FIG. 2. Referring to FIG. 5A, the voltage drop V_{CS-P-H} across the resistor R_{CS} is corresponding to a high voltage level of the power voltage V_{IN}, the voltage drop V_{CS-P-L} across the resistor R_{CS} is corresponding to a low voltage level of the power voltage V_{IN}, and the voltage drop V_{CS-P-O} across the resistor R_{CS} is corresponding to a very low output voltage V_{O}, e.g. when initially powered. Based on the voltage drop V_{CS-P-H} and the voltage drop V_{CS-P-L} shown in FIG. 5A, it is obvious that different voltage levels of the limit signal V_{LIMIT} are provided respectively for different voltage levels of the power voltage V_{IN} so that the effect regarding the occurrence of signal propagation delay can be compensated. However, the voltage drop V_{CS-P-O} may be limited to be a very low value in that the limit signal V_{LIMIT} is very low at the beginning of a period as shown in FIG. 5A. That is, if the limit signal V_{LIMIT} in FIG. 2 is applied, the energy, transferred to the rectification load capacitor C_{O}, is quite limited when initially powered. Therefore, in case that the rectification load capacitor C_{O} is connected with other resistive load in parallel, the limit signal V_{LIMIT} in FIG. 2 may result in generating an undesirable low output voltage V_{O}.

FIG. 5B shows the related signal waveforms during a period regarding the operation of the power supply 400 shown in FIG. 4A so as to illustrate the potential result generated based on the limit signal V_{LIMIT} in FIG. 4B. Referring to FIG. 5B, the voltage drop V_{CS-I-H} across the resistor R_{CS} is corresponding to a high voltage level of the power voltage V_{IN}, the voltage drop V_{CS-I-L} across the resistor R_{CS} is corresponding to a low voltage level of the power voltage V_{IN}, and the voltage drop V_{CS-I-O} across the resistor R_{CS} is corresponding to a very low output voltage V_{O}, e.g. when initially powered. The voltage drop V_{CS-I-H} and the voltage drop V_{CS-I-L} in FIG. 5B are similar to the voltage drop V_{CS-P-H} and the voltage drop V_{CS-P-L} in FIG. 5A, and for the sake of brevity, further discussion on the related compensation thereof is omitted. As shown in FIG. 5B, the limit signal V_{LIMIT} is predetermined to be a higher level at the beginning of a period, and therefore the voltage drop V_{CS-I-O} is able to reach a higher value at the beginning of a period. That is, if the limit signal V_{LIMIT} in FIG. 4B is applied, the energy, transferred to the rectification load capacitor C_{O}, is higher in comparison with the result generated based on the limit signal V_{LIMIT} shown in FIG. 5A. Accordingly, the case of generating an undesirable low output voltage V_{O} when initially powered is not likely to occur. A result of simulation is also able to verify that the output voltage V_{O} generated based on the limit signal V_{LIMIT} shown in FIG. 4B is capable of reaching a desirable voltage level faster than the output voltage V_{O} generated based on the limit signal V_{LIMIT} shown in FIG. 2.

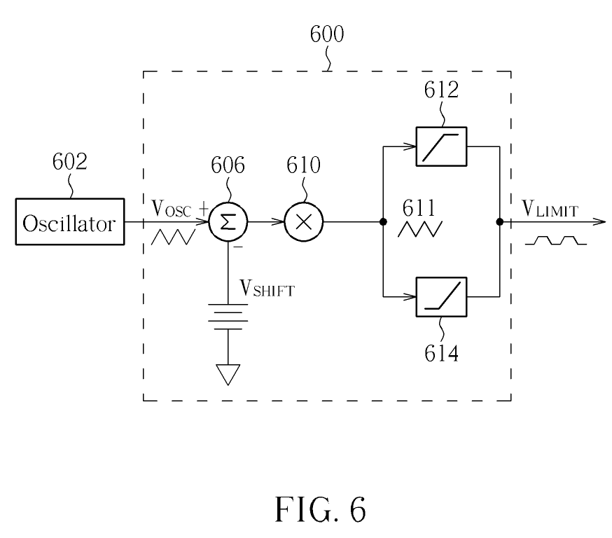

FIG. 6 is a schematic diagram showing a limit signal generator 600 for generating the limit signal V_{LIMIT} in FIG. 4B. The limit signal generator 600 functions to convert a triangular signal V_{OSC} generated by an oscillator 602 to a limit signal V_{LIMIT}. As shown in FIG. 6, the limit signal generator 600 makes use of an adder 606 and a scaler 610 for performing a linear adjustment on the triangular signal V_{OSC} so as to generate another triangular signal 611, i.e. an adjusted signal. The adder 606 is utilized to subtract an offset signal V_{SHIFT} from the triangular signal V_{OSC} for performing a DC level adjustment. The scaler 610 performs a slope adjustment on an output signal of the adder 606 for generating the triangular signal 611. Since the related adjustments are all linear, the triangular signal 611 is different from the triangular signal V_{OSC} only in the slope and the DC level. That is, the periods and the corresponding rising and falling turning initial points of the triangular signal 611 and the triangular signal V_{OSC} are substantially the same.

The dampers 612 and 614 are utilized to perform clamping operations on the triangular signal 611 for generating the limit signal V_{LIMIT}. If the value of the triangular signal 611 is greater than a predetermined value such as a voltage V_{HOLD-MAX} determined by the clamper 612, the damper 612 will clamp the triangular signal 611 for generating the limit signal V_{LIMIT} having the voltage V_{HOLD-MAX}. Alternatively, if the value of the triangular signal 611 is less than another predetermined value such as a voltage V_{HOLD-MIN} determined by the damper 614, the clamper 614 will clamp the triangular signal 611 for generating the limit signal V_{LIMIT} having the voltage V_{HOLD-MIN}. Otherwise, if the value of the triangular signal 611 is within a range between the voltage V_{HOLD-MAX} and the voltage V_{HOLD-MIN}, the value of the limit signal V_{LIMIT} is identical to the value of the triangular signal 611. Accordingly, as shown in FIG. 4B, the limit signal V_{LIMIT} sequentially experiences a holding period P_{HL}, a rising period P_{R} and another holding period P_{HH} during a rising period P_{RISE} of the triangular signal V_{OSC}. In other words, the adder 606 and the scaler 610 are working together for determining the value of the limit signal V_{LIMIT} during the rising period P_{R}. The damper 612 functions to hold the limit signal V_{LIMIT} at the voltage V_{HOLD-MAX} during the holding period P_{HH}. The damper 614 functions to hold the limit signal V_{LIMIT} at the voltage V_{HOLD-MIN} during the holding period P_{HL}.

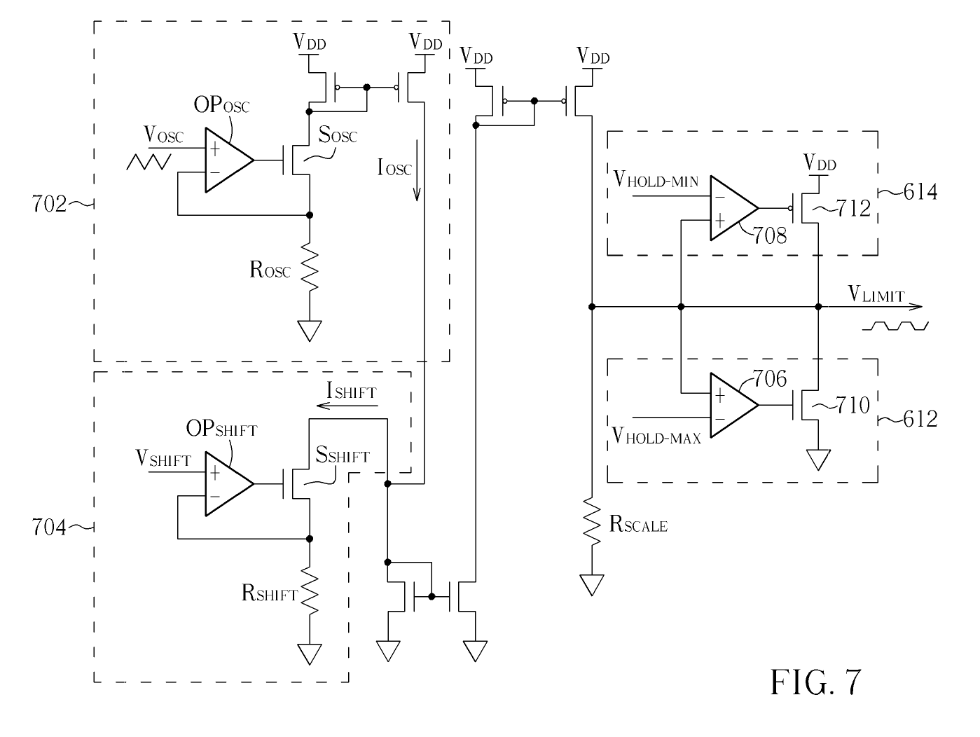

FIG. 7 shows a circuit embodiment of the limit signal generator 600 in FIG. 6. However, the circuit embodiment in FIG. 7 is not meant thereto limit the embodiment of the present invention, and the limit signal generator 600 can be realized with other circuits different from the circuit embodiment in FIG. 7.

Referring to FIG. 7, a voltage-to-current converter 702 is utilized for converting the triangular signal V_{OSC} into a current signal I_{OSC}. The voltage-to-current converter 702 comprises a comparator OP_{OSC}, a resistor R_{OSC}, a switch S_{OSC}, and a current mirror composed of two transistors. A voltage-to-current converter 704 is utilized for converting the offset signal V_{SHIFT} into a current signal I_{SHIFT}. The voltage-to-current converter 704 comprises a comparator OP_{SHIFT}, a resistor R_{SHIFT}, and a switch S_{SHIFT}. A current difference signal, generated by subtracting the current signal I_{SHIFT} from the current signal I_{OSC}, is forwarded to a gain resistor R_{SCALE} via two current mirrors. The gain resistor R_{SCALE} functions as a scaler. The resistance of the gain resistor R_{SCALE} is a first resistance, and the resistance of the resistor R_{OSC} is a second resistance. A ratio of the first resistance to the second resistance can be used to determine the rising slope of the limit signal V_{LIMIT} during the rising period P_{R}. Please continue referring to FIG. 7, the damper 612 comprises a comparator 706 and a switch 710. If the voltage V_{SCALE} across the gain resistor R_{SCALE} is greater than the voltage V_{HOLD-MAX}, the output of the comparator 706 will turn on the switch 710 for pulling down the limit signal V_{LIMIT} by a low voltage source, which means that the limit signal V_{LIMIT} cannot exceed the voltage V_{HOLD-MAX}. Similarly, the clamper 614 comprises a comparator 708 and a switch 712 as shown in FIG. 7. If the voltage V_{SCALE} across the gain resistor R_{SCALE} is less than the voltage V_{HOLD-MIN}, the output of the comparator 708 will turn on the switch 712 for pulling up the limit signal V_{LIMIT} by a high voltage source V_{DD}, which means that the limit signal V_{LIMIT} cannot fall below the voltage V_{HOLD-MIN}. When the voltage V_{SCALE} across the gain resistor R_{SCALE} is within a range between the voltage V_{HOLD-MAX} and the voltage V_{HOLD-MIN}, both the switch 712 and the switch 710 are turned off, and therefore the limit signal V_{LIMIT} is identical to the voltage V_{SCALE}. In other words, the dampers 612 and 614 are working together for clamping the voltage V_{SCALE} between the voltage V_{HOLD-MAX} and the voltage V_{HOLD-MIN} so as to generate the limit signal V_{LIMIT}.

In summary, the limit signal, generated based on the embodiment of the present invention, can be provided for fast boosting the output voltage of the power supply from initial zero level upwards. Therefore, the output voltage of the power supply is capable of reaching a desirable high value in a short time after the power supply is initially powered, and the aforementioned problem of generating an undesirable low output voltage due to initial small power limit can be solved.

The present invention is by no means limited to the embodiments as described above by referring to the accompanying drawings, which may be modified and altered in a variety of different ways without departing from the scope of the present invention. Thus, it should be understood by those skilled in the art that various modifications, combinations, sub-combinations and alternations might occur depending on design requirements and other factors insofar as they are within the scope of the appended claims or the equivalents thereof.

What is claimed is:

1. A limit signal generator for converting a triangular signal into a limit signal, the limit signal comprising a first holding period, a second holding period and a rising period, the limit signal sequentially experiencing the first holding period, the rising period and the second holding period during a corresponding rising period of the triangular signal, the limit signal generator comprising:
a scaler for determining a slope of the limit signal during the rising period;
an adder for determining a value of the limit signal during the rising period by adding an offset signal to the triangular signal;
a first damper for clamping the limit signal to be a first predetermined value during the first holding period; and
a second damper for clamping the limit signal to be a second predetermined value during the second holding period.

2. The limit signal generator of claim 1, wherein the adder comprises:
a first voltage-to-current converter for converting the triangular signal into a triangular current; and
a second voltage-to-current converter for converting the offset signal into an offset current;
wherein the adder outputs a difference current of the triangular current and the offset current.

3. The limit signal generator of claim 1, wherein the scaler comprises a first resistor having a first resistance, the adder comprises a second resistor having a second resistance, and a ratio of the first resistance to the second resistance has an effect on the slope of the limit signal during the rising period.

4. The limit signal generator of claim 1, wherein:
the adder receives the triangular signal and the offset signal;
the scaler receives an output of the adder for generating an adjusted signal; and
the first damper and the second damper monitor the adjusted signal for limiting the adjusted signal to be within a range between the first predetermined value and the second predetermined value.

5. The limit signal generator of claim 4, wherein the first damper comprises:
a first comparator for comparing the adjusted signal with the first predetermined value; and
a first switch controlled by an output of the first comparator, the first switch comprising a first end and a second end for receiving a high power voltage and the adjusted signal respectively.

6. The limit signal generator of claim 5, wherein the second damper comprises:
a second comparator for comparing the adjusted signal with the second predetermined value; and
a second switch controlled by an output of the second comparator, the second switch comprising a first end and a second end for receiving a low power voltage and the adjusted signal respectively.

7. The limit signal generator of claim 1, wherein the first predetermined value is less than the second predetermined value.

8. A pulse width modulation (PWM) control circuit, comprising:
an oscillator for generating a triangular signal;
a limit signal generator for generating a limit signal based on the triangular signal, the limit signal comprising a first holding period, a second holding period and a rising period, the limit signal sequentially experiencing the first holding period, the rising period and the second holding period during a corresponding rising period of the triangular signal, the limit signal being a first predetermined value during the first holding period and a second predetermined value during the second holding period;
a power switch; and
a control circuit for controlling the power switch by comparing the limit signal with a detection signal regarding a current flowing through the power switch.

9. The pulse width modulation control circuit of claim 8, wherein the first predetermined value is less than the second predetermined value.

10. The pulse width modulation control circuit of claim 8, wherein the limit signal generator comprises:
a scaler for determining a slope of the limit signal during the rising period;
an adder for determining a value of the limit signal during the rising period by adding an offset signal to the triangular signal;
a first damper for clamping the limit signal to be the first predetermined value during the first holding period; and
a second damper for clamping the limit signal to be the second predetermined value during the second holding period.

11. A pulse width modulation control method, comprising:
receiving a triangular signal;
performing a plurality of following steps sequentially for outputting a limit signal during a corresponding rising period of the triangular signal:
retaining the limit signal to be a first predetermined value during a first holding period;
increasing the limit signal gradually from the first predetermined value upwards to a second predetermined value during a rising period; and
retaining the limit signal to be the second predetermined value during a second holding period; and
comparing the limit signal with a detection signal regarding a current flowing through a power switch for controlling the power switch.

12. The pulse width modulation control method of claim 11, further comprising:
performing a linear adjustment on the triangular signal for generating an adjusted signal; and
clamping the adjusted signal to be within a range between the first predetermined value and the second predetermined value for outputting the limit signal.
